(19) United States
(12) Patent Application Publication
(10) Pub. No.: US 2016/0172357 A1
(43) Pub. Date: Jun. 16, 2016

(54) SEMICONDUCTOR DEVICE AND METHOD OF FABRICATING THE SAME

(71) Applicant: Hyun-Seung SONG, Incheon (KR)

(72) Inventor: Hyun-Seung SONG, Incheon (KR)

(21) Appl. No.: 14/813,484

(22) Filed: Jul. 30, 2015

(30) Foreign Application Priority Data
Dec. 15, 2014 (KR) 10-2014-0180114

(51) Int. Cl. H01L 27/088; H01L 29/417; H01L 29/08; H01L 23/535

(52) U.S. Cl. CPC H01L 27/0886; H01L 23/535; H01L 29/41783; H01L 29/0847

(57) ABSTRACT

A semiconductor device includes a first active region and a second active region spaced apart from each other, a gate electrode on the first active region and the second active region, the gate electrode intersecting the first active region and the second active region, a first source/drain and a second source/drain on sides of the gate electrode, the first source/drain and the second source/drain spaced apart from each other, and a contact including a first portion on the first source/drain, a second portion on the second source drain and a connection portion interconnecting the first portion and the second portion, the first portion and the second portion having an upper surface arranged to be coplanar with an upper surface of the connection portion, and the first portion and the second portion having a height in a vertical direction different from a height of the connection portion.

### CROSS-REFERENCE TO RELATED APPLICATION

This application claims priority from Korean Patent Application No. 10-2014-0180114 filed on Dec. 15, 2014 in the Korean Intellectual Property Office, and all the benefits accruing therefrom under 35 U.S.C. 119, the contents of which in its entirety are herein incorporated by reference.

### BACKGROUND

1. Field

Example embodiments of the present inventive concepts relate to a semiconductor device and a method of fabricating the same.

2. Description of the Related Art

Recently, functions of semiconductor devices have been significantly developed with rapid supply of information media. Recent semiconductor products are required to have characteristics of relatively low cost for competitiveness and relatively high integration for improved quality. In order to achieve relatively high integration, scaling down of semiconductor devices has been in progress.

Research has been conducted to increase the operating speed of semiconductor devices and increase an integration degree of semiconductor devices. Semiconductors include discrete devices (e.g., MOS transistors), and gates of the MOS transistors have been gradually reduced and lower channel regions of the gates also have been gradually reduced according to the integration of semiconductor devices.

As the gap between the gates of a transistor has been reduced, the gap between the gates of the transistor and source/drain contacts of the transistor has been reduced.

### SUMMARY

Some example embodiments of the present inventive concepts provide a semiconductor device in which a source/drain contact is formed to have an uneven bottom surface, thereby improving reliability and device performance.

Other example embodiments of the present inventive concepts provide a method of fabricating a semiconductor device in which a source/drain contact is formed to have an uneven bottom surface, thereby improving reliability and device performance.

However, example embodiments of the present inventive concepts are not restricted to the one set forth herein. Example embodiments of the present inventive concepts which are not mentioned herein will become more apparent to one of ordinary skilled in the art to which the present inventive concepts pertain by referencing the detailed description given below.

According to example embodiments of the present inventive concepts, a semiconductor device includes a first active region and a second active region spaced apart from each other, a gate electrode on the first active region and the second active region, the gate electrode intersecting the first active region and the second active region, a first source/drain and a second source/drain on sides of the gate electrode and spaced apart from each other, and a contact including a first portion on the first source/drain, a second portion on the second source/drain and a connection portion interconnecting the first portion and the second portion, the first portion and the second portion having an upper surface arranged to be coplanar with an upper surface of the connection portion, and the first portion and the second portion having a height in a vertical direction different from a height of the connection portion.

In example embodiments of the present inventive concepts, the height of the first portion and the height of the second portion may be greater than the height of the connection portion.

In example embodiments of the present inventive concepts, the height of the first portion and the height of the second portion may be the same.

In example embodiments of the present inventive concepts, the connection portion may be between the first source/drain and the second source/drain.

In example embodiments of the present inventive concepts, the semiconductor device may further include an interlayer insulating layer covering the gate electrode, the first source/drain and the second source/drain, the interlayer insulating layer including a contact hole having a first trench portion, a second trench portion and a connection trench portion, and the first trench portion corresponds to the first portion of the contact, the second trench portion corresponds to the second portion of the contact, and the connection trench portion corresponds to the connection portion of the contact.

In example embodiments of the present inventive concepts, a height from an upper surface of the gate electrode to an upper surface of the interlayer insulating layer may be the same as the height of the connection portion.

In example embodiments of the present inventive concepts, the contact may include a barrier layer along a side wall and a bottom surface of the contact hole, and a filling layer on the barrier layer to fill the contact hole, and the filling layer may not be divided by the barrier layer.

In example embodiments of the present inventive concepts, the contact may include a barrier layer along a side wall and a bottom surface of the contact hole, and a filling layer on the barrier layer to fill the contact hole, and the barrier layer may include a protrusion protruding from the bottom surface of the contact hole.

In example embodiments of the present inventive concepts, the filling layer may be divided into at least two sections by the protrusion of the barrier layer.

In example embodiments of the present inventive concepts, the barrier layer along the side wall of the contact hole may have a first thickness T1 and the protrusion of the barrier layer may have a second thickness T2, and T2>T1.

In example embodiments of the present inventive concepts, the protrusion of the barrier layer may have a lower portion having a first thickness T1 and an upper portion having a second thickness T2, and T2<T1.

In example embodiments of the present inventive concepts, the semiconductor device may further include a third active region adjacent to and spaced apart from the first active region, the third active region intersecting the gate electrode, and a third source/drain on sides of the gate electrode. The third source/drain may be in contact with the first source/drain, and not in contact with the second source/drain.

In example embodiments of the present inventive concepts, the first portion may extend onto the third source/drain.

In example embodiments of the present inventive concepts, the first source/drain and the second source/drain may be elevated source/drains.

In example embodiments of the present inventive concepts, each of the first active region and the second active region may be a fin-type active pattern.

In example embodiments of the present inventive concepts, the first source/drain may overlap the first active region, and the second source/drain may overlap the second active region.

In example embodiments of the present inventive concepts, no active region may be between the first active region and the second active region.

According to example embodiments of the present inventive concepts, a semiconductor device includes a first active region and a second active region spaced apart from each other, a gate electrode on the first active region and the second active region, the gate electrode intersecting the first active region and the second active region, a first source/drain and a second source/drain on sides of the gate electrode and spaced apart from each other, the first source/drain overlapping the first active region and the second source/drain overlapping the second active region, an interlayer insulating layer covering the gate electrode, the first source/drain and the second source/drain, and a contact in the interlayer insulating layer, the contact including a first portion on the first source/drain, a second portion on the second source/drain and a connection portion interconnecting the first portion and the second portion, the first portion having a bottom surface and the second portion having a bottom surface lower than a bottom surface of the connection portion based on an upper surface of the interlayer insulating layer.

In example embodiments of the present inventive concepts, the bottom surface of the connection portion may be higher than an upper surface of the first source/drain and an upper surface of the second source/drain based on the upper surface of the interlayer insulating layer.

In example embodiments of the present inventive concepts, an upper surface of the first portion, an upper surface of the second portion, and an upper surface of the connection portion may be arranged to be coplanar with each other.

In example embodiments of the present inventive concepts, the interlayer insulating layer may include a contact hole corresponding with the contact, the contact hole may have an uneven bottom surface corresponding to the bottom surface of the first portion, the bottom surface of the second portion and the bottom surface of the connection portion, and the contact may include a barrier layer along a side wall and a bottom surface of the contact hole and a filling layer on the barrier layer to fill the contact hole.

In example embodiments of the present inventive concepts, the filling layer included in the first portion, the second portion and the connection portion may be an integral structure.

In example embodiments of the present inventive concepts, the barrier layer may further include a protrusion protruding from the bottom surface of the contact hole, and the filling layer may be divided into at least two sections by the protrusion.

In example embodiments of the present inventive concepts, no active region may be between the first active region and the second active region.

According to example embodiments of the present inventive concepts, a semiconductor device includes first, second, third and fourth fin-type active patterns spaced apart from each other and sequentially arranged in one direction, a field insulating layer covering a portion of each side wall of the first, second, third and fourth fin-type active patterns, a gate electrode on the field insulating layer, the gate electrode intersecting the first, second, third and fourth fin-type active patterns and extending in the one direction, a first source/drain on the first fin-type active pattern and a second source/drain on the second fin-type active pattern, the first and second source/drains on sides of the gate electrode and contacting each other, a third source/drain on the third fin-type active pattern and a fourth source/drain on the fourth fin-type active pattern, the third and fourth source/drains on sides of the gate electrode and contacting each other, the third source/drain not contacting the second source/drain, and a contact including a first portion connected to the first source/drain and the second source/drain, a second portion connected to the third source/drain and the fourth source/drain and a connection portion interconnecting the first portion and the second portion, the first portion and the second portion having an upper surface arranged to be coplanar with an upper surface of the connection portion, and the first portion and the second portion having a height different from a height of the connection portion.

In example embodiments of the present inventive concepts, a bottom surface of the first portion and a bottom surface of the second portion may be lower than a bottom surface of the connection portion based on an upper surface of the field insulating layer.

In example embodiments of the present inventive concepts, a part of the connection portion may pass through a gap between the second source/drain and the third source/drain.

In example embodiments of the present inventive concepts, a bottom surface of the connection portion may be higher than an upper surface of the field insulating layer.

In example embodiments of the present inventive concepts, the interlayer insulating layer may include a contact hole, the contact hole may have an uneven bottom surface corresponding to the bottom surface of the first portion, the bottom surface of the second portion and the bottom surface of the connection portion, and the contact may include a barrier layer along a side wall and a bottom surface of the contact hole, and a filling layer on the barrier layer to fill the contact hole.

In example embodiments of the present inventive concepts, the filling layer included in the first portion, the second portion and the connection portion may be an integral structure.

According to example embodiments of the present inventive concepts, a method for fabricating a semiconductor device includes forming a gate electrode on a first active region and a second active region spaced apart from each other, the gate electrode intersecting the first active region and the second active region, forming a first source/drain and a second source/drain on sides of the gate electrode and spaced apart from each other, the first source/drain overlapping the first active region and the second source/drain overlapping the second active region, forming an interlayer insulating layer covering the gate electrode, the first source/drain and the second source/drain, forming a first trench and a second trench in the interlayer insulating layer, the first trench exposing the first source/drain and the second trench exposing the second source/drain, and forming a connection trench and a first contact hole simultaneously in the interlayer insulating layer, the connection trench interconnecting the first trench and the second trench and the first contact hole exposing an upper surface of the gate electrode.

In example embodiments of the present inventive concepts, the method may further include forming a sacrificial pattern in the interlayer insulating layer prior to the forming a connection trench, the sacrificial pattern filling each of the first trench and the second trench, removing the sacrificial pattern after the forming a connection trench to form a second contact hole including the first trench, the second trench and the connection trench, and forming a source/drain contact filling the second contact hole.

In example embodiments of the present inventive concepts, the method may further include forming a first portion of a contact filling the first trench and a second portion of the contact filling the second trench prior to forming the connection trench, and forming a connection portion of the contact filling the connection trench after the forming a connection trench, the connection portion contacting the first portion of the contact and the second portion of the contact.

In example embodiments of the present inventive concepts, forming the connection portion may further include forming a gate contact filling the first contact hole.

According to example embodiments of the present inventive concepts, a semiconductor device includes first and second fin-type active patterns spaced apart from each other, a field insulating layer covering a portion of each side wall of the first and second fin-type active patterns, and a first source/drain contact on the first fin-type active pattern and a second source/drain contact on the second fin-type active pattern, the first and second source/drain contacts connected by a connection portion, the connection portion spaced apart from the field insulating layer.

In example embodiments of the present inventive concepts, a bottom surface of the first source/drain contact and a bottom surface of the second source/drain contact may be lower than a bottom surface of the connection portion based on an upper surface of the field insulating layer.

In example embodiments of the present inventive concepts, a top surface of the first source/drain contact, a top surface of the second source/drain contact, and a top surface of the connection portion may be arranged to be coplanar with each other.

### BRIEF DESCRIPTION OF THE DRAWINGS

The above and other features and advantages of the present inventive concepts will become more apparent by describing in detail example embodiments thereof with reference to the attached drawings in which:

FIG. 1 is a layout diagram illustrating a semiconductor device according to example embodiments of the present inventive concepts;

FIG. 2 is a cross-sectional view taken along the line A-A of FIG. 1;

FIG. 3 is a cross-sectional view taken along the line B-B of FIG. 1;

FIG. 4 is a cross-sectional view taken along the line C-C of FIG. 1;

FIG. 5 is a cross-sectional view excluding a first contact from FIG. 4;

FIG. 6 is a cross-sectional view taken along the line D-D of FIG. 1;

FIG. 7 is a diagram illustrating a semiconductor device according to example embodiments of the present inventive concepts;

FIG. 8 is a diagram illustrating a semiconductor device according to example embodiments of the present inventive concepts;

FIG. 9 and FIG. 10 are diagrams illustrating a semiconductor device according to example embodiments of the present inventive concepts;

FIG. 11 is a diagram illustrating a semiconductor device according to example embodiments of the present inventive concepts;

FIG. 12 and FIG. 13 are diagrams illustrating a semiconductor device according to example embodiments of the present inventive concepts;

FIG. 14 is a layout diagram illustrating a semiconductor device according to example embodiments of the present inventive concepts;

FIG. 15 is a cross-sectional view taken along the line C-C of FIG. 14;

FIG. 16 is a diagram illustrating a semiconductor device according to example embodiments of the present inventive concepts;

FIG. 17 to FIG. 24 are diagrams illustrating intermediate process steps of a method of fabricating a semiconductor device according to example embodiments of the present inventive concepts;

FIG. 25 to FIG. 27 are diagrams illustrating intermediate process steps of a method of fabricating a semiconductor device according to example embodiments of the present inventive concepts;

FIG. 28 is a block diagram of an electronic system including semiconductor devices according to example embodiments of the present inventive concepts; and

FIG. 29 and FIG. 30 are diagrams illustrating examples of a semiconductor system to which semiconductor devices according to example embodiments of the present inventive concepts can be applied.

### DETAILED DESCRIPTION

The present inventive concepts will now be described more fully hereinafter with reference to the accompanying drawings, in which example embodiments are shown. The inventive concepts may, however, be embodied in different forms and should not be construed as limited to the example embodiments set forth herein. Rather, these embodiments are provided so that this disclosure will be thorough and complete, and will fully convey the scope of the inventive concepts to those skilled in the art. The same reference numbers indicate the same components throughout the specification. In the attached figures, the thickness of layers and regions is exaggerated for clarity.

It will be understood that when an element or layer is referred to as being “connected to,” or “coupled to” another element or layer, it can be directly connected to or coupled to another element or layer or intervening elements or layers may be present. In contrast, when an element is referred to as being “directly connected to” or “directly coupled to” another element or layer, there are no intervening elements or layers present Like numbers refer to like elements throughout. As used herein, the term “and/or” includes any and all combinations of one or more of the associated listed items.

It will also be understood that when a layer is referred to as being “on” another layer or substrate, it can be directly on the other layer or substrate, or intervening layers may also be present. In contrast, when an element is referred to as being “directly on” another element, there are no intervening elements present.

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present inventive concepts.

The use of the terms “a” and “an” and “the” and similar referents in the context of describing the inventive concepts (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

Unless defined otherwise, all technical and scientific terms used herein have the same meaning as commonly understood by one of ordinary skill in the art to which the inventive concepts belong. It is noted that the use of any and all examples, or example terms provided herein is intended merely to better illuminate the inventive concepts and is not a limitation on the scope of the inventive concepts unless otherwise specified. Further, unless defined otherwise, all terms defined in generally used dictionaries may not be overly interpreted.

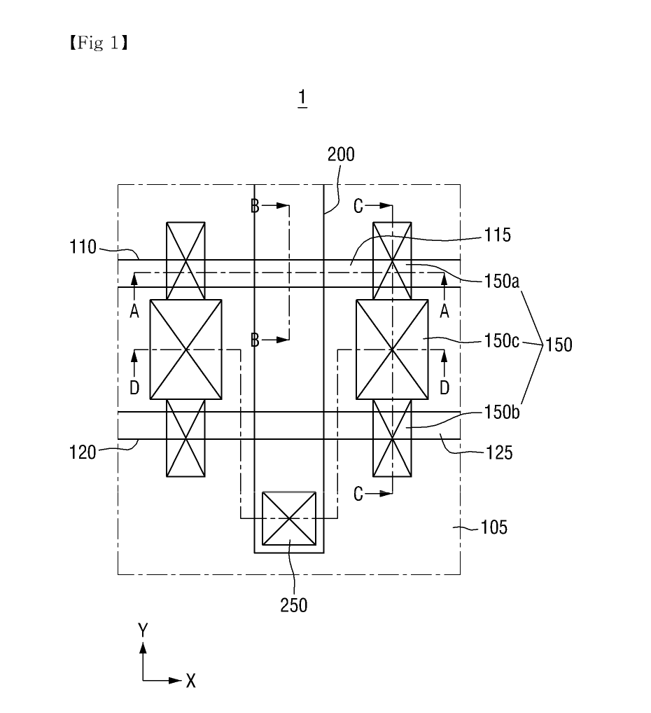

A semiconductor device according to example embodiments of the present inventive concepts will be described with reference to FIG. 1 to FIG. 6.

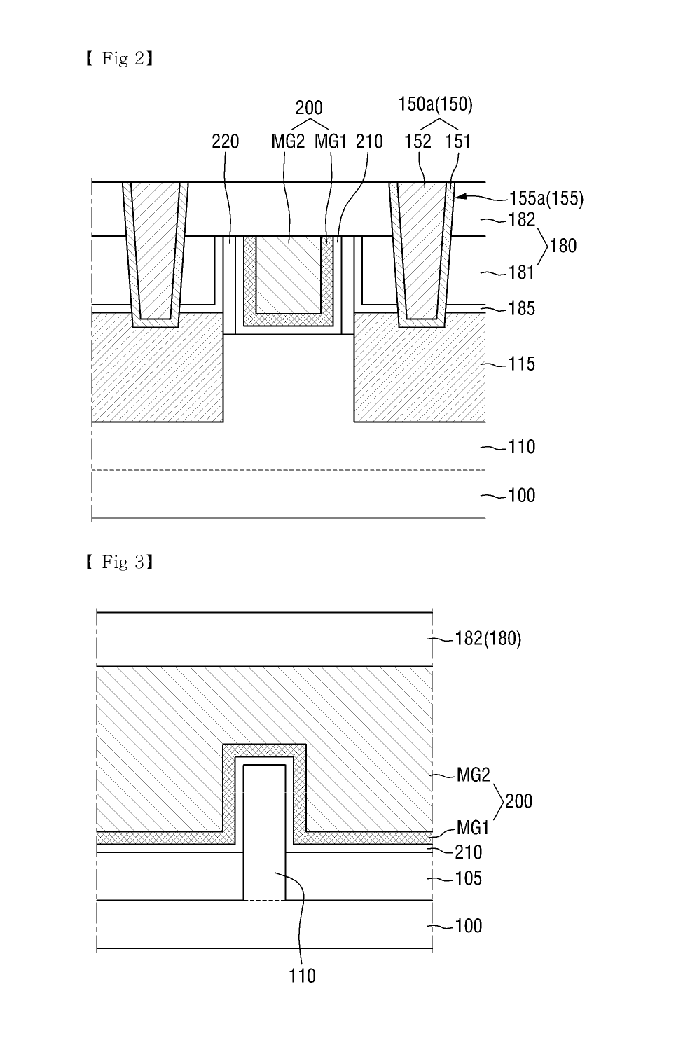

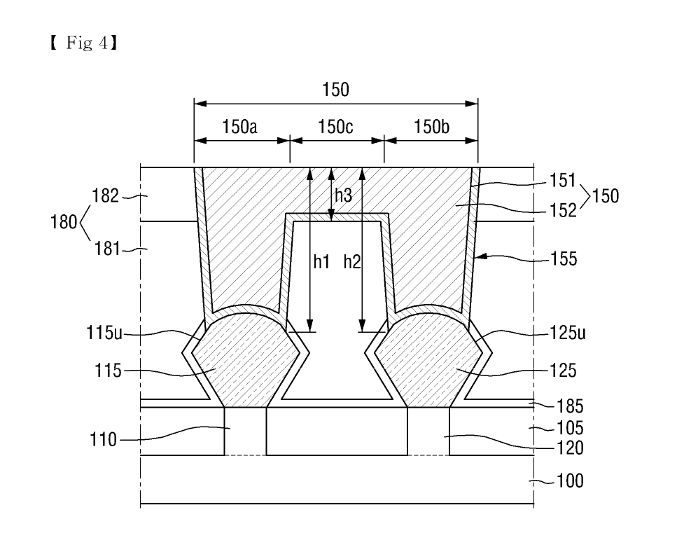

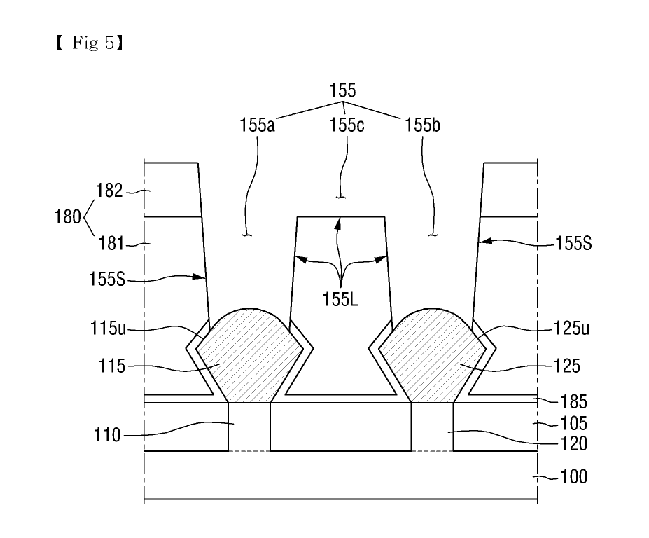

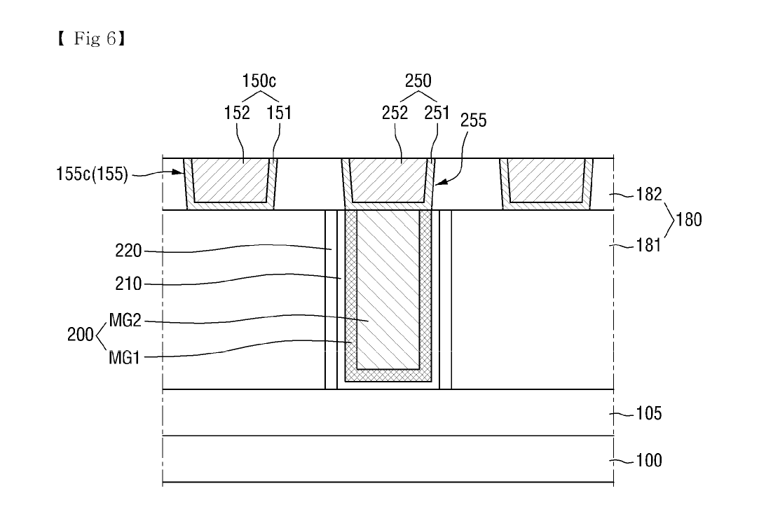

FIG. 1 is a layout diagram illustrating a semiconductor device according to example embodiments of the present inventive concepts. FIG. 2 is a cross-sectional view taken along the line A-A of FIG. 1. FIG. 3 is a cross-sectional view taken along the line B-B of FIG. 1. FIG. 4 is a cross-sectional view taken along the line C-C of FIG. 1. FIG. 5 is a cross-sectional view excluding a first contact from FIG. 4. FIG. 6 is a cross-sectional view taken along the line D-D of FIG. 1.

Referring to FIG. 1 to FIG. 6, a semiconductor device 1 according to example embodiments of the present inventive concepts may include a first active region 110, a second active region 120, a gate electrode 200, a first source/drain 115, a second source/drain 125, and a first contact 150.

The first active region 110 and the second active region 120 may be defined by a field insulating layer 105. The first active region 110 and the second active region 120 may be spaced apart from each other.

The first active region 110 and the second active region 120 may be extended, for example, in a first direction X. The first active region 110 and the second active region 120 may be arranged in a second direction Y.

The field insulating layer 105 may be provided between the first active region 110 and the second active region 120. In semiconductor devices according to example embodiments of the present inventive concepts, the first active region 110 and the second active region 120 may be most adjacent to each other. That is, the field insulating layer 105 may be disposed between the first active region 110 and the second active region 120, and any other active region may not be interposed therebetween.

Each of the first active region 110 and the second active region 120 may be any one of a single channel active region or multi-channel active region. In the semiconductor device 1 according to example embodiments of the present inventive concepts, the first active region 110 and the second active region 120 are described as fin-type active patterns protruding from a substrate 100.

Since the field insulating layer 105 covers a part of side walls of the first active region 110 and a part of side walls of the second active region 120, at least a part of each of the first active region 110 and the second active region 120 may protrude further upward than the field insulating layer 105. That is, at least a part of an upper surface of the first active region 110 and at least a part of an upper surface of the second active region 120 may protrude further upward than an upper surface of the field insulating layer 105.

The substrate 100 may be, for example, bulk silicon or silicon-on-insulator (SOI). Alternatively, the substrate 100 may be a silicon substrate, or may include other materials, for example, silicon germanium, indium antimonide, lead telluride, indium arsenide, indium phosphide, gallium arsenide, or gallium antimonide. Alternatively, the substrate 100 may be obtained by forming an epitaxial layer on a base substrate.

The field insulating layer 105 may include one of, for example, an oxide layer, a nitride layer, an oxynitride layer or a combination thereof, is but not limited thereto.

Each of the first active region 110 and the second active region 120 which are fin-type active patterns may be a part of the substrate 100, and may include an epitaxial layer grown from the substrate 100.

The first active region 110 and the second active region 120 may include, for example, silicon or germanium which is an elemental semiconductor material. Furthermore, the first active region 110 and the second active region 120 may include compound semiconductors, for example, IV-IV family compound semiconductors or III-V family compound semiconductors.

As an example of IV-IV family compound semiconductors, each of the first active region 110 and the second active region 120 may be a binary compound or a ternary compound including at least two of carbon (C), silicon (Si), germanium (Ge) and tin (Sn), or may be a compound formed by doping an IV family element thereto.

As an example of III-V family compound semiconductors, each of the first active region 110 and the second active region 120 may be one of a binary compound, a ternary compound and quaternary compound formed by bonding at least one of aluminum (Al), gallium (Ga) and indium (In) as III family element and one of phosphorus (P), arsenic (As) and antimony (Sb) as V family element.

In the semiconductor device 1 according to example embodiments of the present inventive concepts, the first active region 110 and the second active region 120 are described as silicon fin-type active pattern including silicon.

The gate electrode 200 may extend in the second direction Y to intersect the first active region 110 and the second active region 120. The gate electrode 200 may be formed on the first active region 110, the second active region 120 and the field insulating layer 105.

In the semiconductor device 1 according to example embodiments of the present inventive concepts, the gate electrode 200 may include metal layers MG1 and MG2. As shown in the drawing, the gate electrode 200 may include two or more metal layers MG1 and MG2 which are stacked. The first metal layer MG1 may serve to regulate a work function, and the second metal layer MG2 may serve to fill a space formed by the first metal layer MG1.

For example, the first metal layer MG1 may include at least one of TiN, TaN, TiC, and TaC. The second metal layer MG2 may include W or Al. Alternatively, the gate electrode 200 may be formed of Si, SiGe and like which are not metal. The gate electrode 200 may be formed through, for example, a replacement process (or a gate last process)), but is not limited thereto.

A gate insulating layer 210 may be formed between the first active region 110 and the gate electrode 200, and between the second active region 120 and the gate electrode 200. The gate insulating layer 210 may be formed along the side wall and the upper surface of the first active region 110 which protrude further upward than the field insulating layer 105, and along the side wall and the upper surface of the second active region 120 which also protrude further upward than the field insulating layer 105. In addition, the gate insulating layer 210 may be interposed between the gate electrode 200 and the field insulating layer 105.

The gate insulating layer 210 may include, for example, a silicon oxide layer, a silicon oxynitride layer, a silicon nitride layer, a germanium oxynitride layer (GeON), a silicon germanium oxide layer (GeSiO) or high dielectric constant materials. The high dielectric constant materials may include one or more among, for example, but not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

A gate spacer 220 may be formed on side walls of the gate electrode 200 extending in the second direction Y. The gate spacer 220 may include at least one of, for example, silicon nitride (SiN), silicon oxynitride (SiON), silicon oxide (SiO₂), silicon carbon oxynitride (SiOCN) and a combination thereof. Although the gate spacer 220 is depicted as a single layer, the gate spacer 220 is not limited thereto and may have a multi-layer structure.

The first source/drain 115 may be formed at both sides of the gate electrode 200. The first source/drain 115 may overlap the first active region 110. The first source/drain 115 may be an elevated source/drain.

The second source/drain 125 may be formed at both sides of the gate electrode 200. The second source/drain 125 may overlap the second active region 120. The second source/drain 125 may be an elevated source/drain.

The first source/drain 115 and the second source/drain 125 may be formed in the vicinity of each other, but spaced apart from each other. The first source/drain 115 and the second source/drain 125 may not contact each other. That is, the first source/drain 115 and the second source/drain 125 on one side of the gate electrode 200 may be spaced apart from each other with the gate electrode 200 interposed therebetween.

In the semiconductor device 1 according to example embodiments of the present inventive concepts, the first source/drain 115 may be formed on the first active region 110, and the second source/drain 125 may be formed on the second active region 120.

Although it is depicted in FIG. 2 and FIG. 4 that a part of the first source/drain 115 fills a recess formed in the first active region 110, and a part of the second source/drain 125 fills a recess formed in the second active region 120, the present disclosure is not limited thereto.

That is, the first source/drain 115 may include an epitaxial layer which covers at least a part of the first active region 110 and protrudes further upward than the field insulating layer 105. The second source/drain 125 may be the same as the first source/drain 115.

In a case where the semiconductor device 1 according to example embodiments of the present inventive concepts is a PMOS transistor, each of the first source/drain 115 and the second source/drain 125 may include compressive stress materials. For example, the compressive stress materials may have a lattice constant larger than that of Si, and may be, for example, SiGe. The compressive stress materials may apply compressive stress to each of the first active region 110 and the second active region 120 so as to improve carrier mobility in a channel region.

On the other hand, in a case where the semiconductor device 1 is an NMOS transistor, each of the first source/drain 115 and the second source/drain 125 may include materials same as those of the first active region 110 and the second active region 120, or tensile stress materials. For example, when the first active region 110 and the second active region 120 are silicon fin-type active pattern, the first source/drain 115 and the second source/drain 125 may include Si or a material having a lattice constant smaller than that of Si (for example, Sic or silicon that contains carbon(Si:C)).

An etch stop layer 185 may be formed on the first source/drain 115 and the second source/drain 125. The etch stop layer 185 may be formed along outer surfaces of the first source/drain 115 and the second source/drain 125 and the upper surface of the field insulating layer 105.

The etch stop layer 185 may include at least one of, for example, silicon nitride (SiN), silicon oxynitride (SiON), silicon oxide (SiO2), silicon carbon oxynitride (SiOCN), silicon carbonitride (SiCN) and a combination thereof.

An interlayer insulating layer 180 may cover the gate electrode 200, the first source/drain 115 and the second source/drain 125. The interlayer insulating layer 180 may be formed on the etch stop layer 185.

The interlayer insulating layer 180 may include a lower interlayer insulating layer 181 and an upper interlayer insulating layer 182. The lower interlayer insulating layer 181 and the upper interlayer insulating layer 182 may be distinguished by, for example, but not limited to, whether the layer is deposited prior to a formation of the gate electrode 200.

The interlayer insulating layer 180 may include at least one of, for example, silicon oxide, silicon nitride, silicon oxynitride and low dielectric constant materials having a dielectric constant lower than that of silicon oxide. The low dielectric constant materials may include, for example, but not limited to, flowable oxide (FOX), torene silazene (TOSZ), undoped silica glass (USG), borosilica glass (BSG), phosphosilaca glass (PSG), borophosphosilica glass (BPSG), plasma enhanced tetra ethyl ortho silicate (PETEOS), fluoride silicate glass (FSG), carbon doped silicon oxide (CDO), xerogel, aerogel, amorphous fluorinated carbon, organo silicate glass (OSG), parylene, bis-benzocyclobutenes (BCB), SiLK, polyimide, porous polymeric material or a combination thereof.

The interlayer insulating layer 180 may include a first contact hole 155 and a second contact hole 255. The second contact hole 255 may be formed on the gate electrode 200 to expose an upper surface of the gate electrode 200.

The first contact hole 155 may be formed on the first source/drain 115 and the second source/drain 125. An upper surface 115u of the first source/drain and an upper surface 125u of the second source/drain may be exposed by the first contact hole 155. That is, the first contact hole 155 may extend in the second direction Y at one side and the other side of the gate electrode 200.

The first contact 150 may be formed within the interlayer insulating layer 180. The first contact 150 may be formed to fill the first contact hole 155. The first contact 150 may be connected to the first source/drain 115 and the second source/drain 125. That is, the first contact 150 may be a common contact to the first source/drain 115 and the second source/drain 125.

In the semiconductor device 1 according to example embodiments of the present inventive concepts, a part of the first contact 150 may be enveloped by the first source/drain 115 and the second source/drain 125.

As shown in FIG. 2, at least a part of the upper surface 115u of the first source/drain 115 and at least a part of the upper surface 125u of the second source/drain 125 may be etched to form a recess in the first source/drain 115 and the second source/drain 125. Since a part of the first contact 150 may be formed within the recess in the first source/drain 115 and the second source/drain 125, the part of the first contact 150 may be enveloped by the first source/drain 115 and the second source/drain 125.

Since the first contact 150 may be connected to both the first source/drain 115 and the second source/drain 125 formed at one side of the gate electrode 200, the first contact 150 may extend in the second direction Y.

The first contact 150 may include a first barrier layer 151 and a first filling layer 152. The first barrier layer 151 may be formed along the first contact hole 155.

The first filling layer 152 may fill the first contact hole 155 on which the first barrier layer 151 is formed. The first filling layer 152 may be formed on the first barrier layer 151.

A second contact 250 may be formed within the interlayer insulating layer 180. The second contact 250 may be formed to fill the second contact hole 255. The second contact 250 may be connected to the gate electrode 200.

Although the second contact 250 is depicted as being positioned at an end of the gate electrode 200 in FIG. 1, it is merely for convenience of description and is not limited thereto.

The second contact 250 may include a second barrier layer 251 and a second filling layer 252. The second barrier layer 251 may be formed along the second contact hole 255.

The second filling layer 252 may fill the second contact hole 255 on which the second barrier layer 251 is formed. The second filling layer 252 may be formed on the second barrier layer 251.

Each of the first barrier layer 151 and the second barrier layer 251 may include, for example, tantalum (Ta), tantalum nitride (TaN), titanium (Ti), titanium nitride (TiN), ruthenium (Ru), cobalt (Co), nickel (Ni), nickel boride (NiB), or tungsten nitride (WN).

Each of the first contact 150 and the second contact 250 may include, for example, aluminum (Al), tungsten (W), copper (Cu), cobalt (Co), or doped polysilicon.

Referring to FIG. 1 and FIG. 4 to FIG. 6, the first contact 150 may include a first portion 150a, a second portion 150b, and a connection portion 150c.

The connection portion 150c of the first contact 150 may be interposed between the first portion 150a of the first contact 150 and the second portion 150b of the first contact 150. That is, the first portion 150a and the second portion 150b of the first contact 150 may be arranged in the second direction Y with the connection portion 150c of the first contact 150 interposed between the first portion 150a and the second portion 150b.

The first portion 150a of the first contact may be disposed on the first source/drain 115. The first portion 150a of the first contact may overlap the first source/drain 115, but may not overlap the second source/drain 125. The first portion 150a of the first contact may be an integral structure formed by a single fabricating process.

The second portion 150b of the first contact may be disposed on the second source/drain 125. The second portion 150b of the first contact may overlap the second source/drain 125, but may not overlap the first source/drain 115. The second portion 150b of the first contact may be an integral structure formed by a single fabricating process.

The connection portion 150c of the first contact may interconnect the first portion 150a of the first contact and the second portion 150b of the first contact. The connection portion 150c of the first contact may be arranged between the first source/drain 115 and the second source/drain 125 which are on one side of the gate electrode 200.

An upper surface of the first portion 150a of the first contact, an upper surface of the second portion 150b of the first contact, and an upper surface of the connection portion 150c of the first contact may be arranged to be coplanar with each other. That is, an upper surface of the first contact 150 may be arranged to be coplanar.

Although a boundary between the upper surface of the first portion 150a of the first contact and an upper surface of the upper interlayer insulating layer 182, and a boundary between the upper surface of the second portion 150b of the first contact and the upper surface of the upper interlayer insulating layer 182 are depicted as being connected into an even shape in FIG. 4, the present disclosure is not limited thereto.

The first portion 150a of the first contact may have a height h1 different from a height h3 of the connection portion 150c of the first contact, and the second portion 150b of the first contact may have a height h2 different from the height h3 of the connection portion 150c of the first contact.

Although it is depicted in FIG. 4 that the height h1 of the first portion 150a of the first contact is substantially same as the height h2 of the second portion 150b of the first contact, it is merely for convenience of description and is not limited thereto. That is, the height h1 of the first portion 150a of the first contact and the height h2 of the second portion 150b of the first contact may be a little bit different from each other depending on a process margin caused during a process of forming the first contact hole 155.

In the semiconductor device 1 according to example embodiments of the present inventive concepts, the height h1 of the first portion 150a of the first contact may be higher than the height h3 of the connection portion 150c of the first contact. Furthermore, the height h2 of the second portion 150b of the first contact may be higher than the height h3 of the connection portion 150c of the first contact.

Alternatively, when measured from an upper surface of the interlayer insulating layer 180, a bottom surface of the first portion 150a of the first contact and a bottom surface of the second portion 150b of the first contact may be deeper than a bottom surface of the connection portion 150c of the first contact. On the other hand, when measured from the upper surface of the field insulating layer 105, the bottom surface of the first portion 150a of the first contact and the bottom surface of the second portion 150b of the first contact may be lower than the bottom surface of the connection portion 150c of the first contact.

In addition, when measured from the upper surface of the interlayer insulating layer 180, the bottom surface of the connection portion 150c of the first contact may be shallower than the upper surface 115u of the first source/drain and the upper surface 125u of the second source/drain.

The height h3 of the connection portion 150c of the first contact may be substantially same as the height of the second contact 250, but is not limited thereto. As used herein, the description “having the same height” may not only mean that the height of the two components being compared are perfectly the same but also may include the slight difference in height which might be caused due to a process margin.

In other words, the distance from the upper surface of the gate electrode 200 to the upper surface of the interlayer insulating layer 180 may be substantially same as the height h3 of the connection portion 150c of the first contact.

Alternatively, the height h3 of the connection portion 150c of the first contact may be substantially same as the thickness of the upper interlayer insulating layer 182, but is not limited thereto. When the upper surface of the gate electrode 200 is further recessed than an upper surface of the gate spacer 220 to form a capping pattern on the upper surface of the gate electrode 200, and therefore, the height h3 of the connection portion 150c of the first contact may be bigger than the thickness of the upper interlayer insulating layer 182.

The height h3 of the connection portion 150c of the first contact may be substantially same as the height of the second contact 250, and therefore, the connection portion 150c of the first contact may not overlap the gate electrode 200 in a thickness direction of the substrate 100.

Thus, capacitance between the connection portion 150c of the first contact and the gate electrode 200 may be reduced. In other words, as the effective capacitance between the first contact 150 and the gate electrode 200 is reduced, a coupling phenomenon between the first contact 150 and the gate electrode 200 may be alleviated, thus improving reliability and performance of the semiconductor device.

The first contact hole 155 may include a first trench 155a, a second trench 155b and a connection trench 155c. The connection trench 155c may be formed between the first trench 155a and the second trench 155b.

The first trench 155a may correspond to the first portion 150a of the first contact, and the second trench 155b may correspond to the second portion 150b of the first contact. In addition, the connection trench 155c may correspond to the connection portion 150c of the first contact.

The first contact hole 155 may has sidewalls 155S and a bottom surface 155L interconnecting sidewall 155S. More specifically, the sidewall 155S of the first contact hole 155 may be a portion formed along the outer surface of the first contact 150 in FIG. 1, and the bottom surface 155L of the first contact hole may be a portion interconnecting the sidewall 155S of the first contact hole.

The first trench 155a may have a bottom surface corresponding to the bottom surface of the first portion 150a of the first contact, the second trench 155b may have a bottom surface corresponding to the bottom surface of the second portion 150b of the first contact, and the connection trench 155c may have a bottom surface corresponding to the connection portion 150c of the first contact.

When measured from the upper surface of the interlayer insulating layer 180, the bottom surface of the first portion 150a of the first contact and the bottom surface of the second portion 150b of the first contact may be deeper than the bottom surface of the connection portion 150c of the first contact.

Therefore, when measured from the upper surface of the interlayer insulating layer 180, the bottom surface of the first trench 155a and the bottom surface of the second trench 155b may be deeper than the bottom surface of the connection trench 155c. That is, the bottom surface 155L of the first contact hole 155 may be uneven in correspondence to the bottom surface of the first contact 150.

Furthermore, since the distance from the upper surface of the gate electrode 200 to the upper surface of the interlayer insulating layer 180 may be substantially same as the height h3 of the connection portion 150c of the first contact, the bottom surface of the connection trench 155c may be, but not limited to, a boundary between the lower interlayer insulating layer 181 and the upper interlayer insulating layer 182.

The first barrier layer 151 may be formed along the sidewall 155S of the first contact hole and the bottom surface 155L of the first contact hole. Furthermore, the first filling layer 152 may be formed on the first barrier layer 151 and fill the first contact hole 155.

In the semiconductor device 1 according to example embodiments of the present inventive concepts, the first filling layer 152 may not be divided by the first barrier layer 151. In other words, the first barrier layer 151 may not have a protrusion which protrudes from the bottom surface 155L of the first contact hole.

Thus, the first filling layer 152 included in the first portion 150a of the first contact, the first filling layer 152 included in the second portion 150b of the first contact, and the first filling layer 152 included in the connection portion 150c of the first contact may be directly connected with each other to form an integral structure.

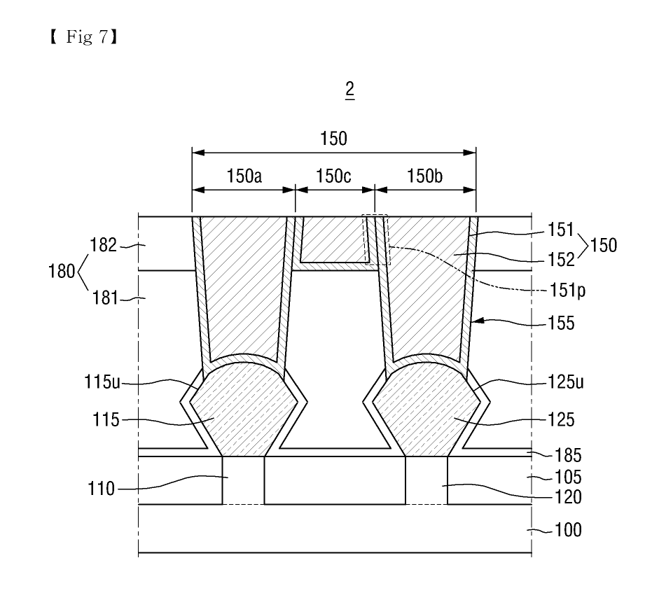

FIG. 7 is a diagram illustrating a semiconductor device according to example embodiments of the present inventive concepts. For convenience of description, differences from the example embodiment described with reference to FIG. 1 to FIG. 6 will be mainly explained. For reference, FIG. 7 may be a cross-sectional view taken along the line C-C of FIG. 1.

Referring to FIG. 7, in a semiconductor device 2 according to example embodiments of the present inventive concepts, the barrier layer 151 may further have a protrusion 151p protruding from the bottom surface 155L of the first contact hole.

The protrusion 151p of the first barrier layer may protrude from the first barrier layer 151 formed along the bottom surface 155L of the first contact hole.

The protrusion 151p of the first barrier layer may protrude from the bottom surface 155L of the first contact hole and extended to the upper surface of the first contact 150. Thus, the first filling layer 152 may be divided into at least two sections by the protrusion 151p of the first barrier layer.

That is, at least two of the first filling layer 152 included in the first portion 150a of the first contact, the first filling layer 152 included in the second portion 150b of the first contact, and the first filling layer 152 included in the connection portion 150c of the first contact may be divided by the protrusion 151p of the first barrier layer.

Thus, at least two of the first filling layer 152 included in the first portion 150a of the first contact, the first filling layer 152 included in the second portion 150b of the first contact, and the first filling layer 152 included in the connection portion 150c of the first contact may not be directly connected with each other.

Furthermore, the protrusion 151p of the first barrier layer may have a thickness which can be thicker than the thickness of the first barrier layer 151 formed along the sidewall 155S of the first contact hole. This is because, unlike the first barrier layer 151 formed along the sidewall 155S of the first contact hole, the protrusion 151p of the first barrier layer may be formed through deposition processes performed two times.

In FIG. 7, the upper surface of the first contact 150 is depicted as being arranged to be coplanar. That is, although the upper surface of the first portion 150a of the first contact, the upper surface of the second portion 150b of the first contact, and the upper surface of the connection portion 150c of the first contact are depicted as being arranged to be coplanar with each other, it is merely for convenience of description and is not limited thereto.

For example, unlike those shown in FIG. 7, a boundary between the upper surface of the first portion 150a of the first contact and an upper surface of the protrusion 151p of the first barrier layer may not be even in shape.

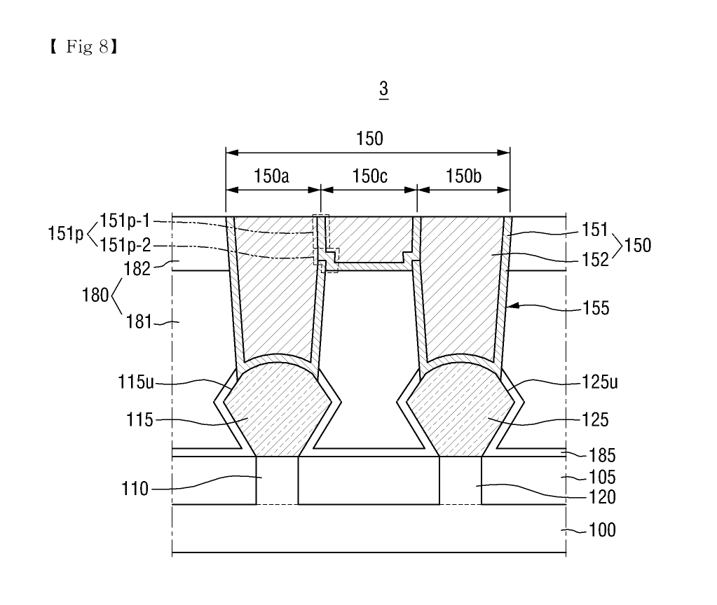

FIG. 8 is a diagram illustrating a semiconductor device according to example embodiments of the present inventive concepts. For convenience of description, differences from the example embodiment described with reference to FIG. 7 will be mainly explained. For reference, FIG. 6 may be a cross-sectional view taken along the line C-C of FIG. 1.

Referring to FIG. 8, in a semiconductor device 3 according to example embodiments of the present inventive concepts, the first barrier layer 151 may further have the protrusion 151p which protrudes from the bottom surface 155L of the first contact hole and which has an upper portion 151p-1 and a lower portion 151p-2.

The protrusion 151p of the first barrier layer may have the lower portion 151p-2 protruding from the first barrier layer 151 formed along the bottom surface 155L of the first contact hole, and the upper portion 151p-1 formed on the lower portion 151p-2 of the protrusion 151p of the first barrier layer.

The lower portion 151p-2 of the protrusion 151p of the first barrier layer may have a thickness different from the thickness of the upper portion 151p-1 of the protrusion 151p of the first barrier layer. More specifically, the thickness of the protrusion 151p of the first barrier layer may not be even at the boundary between the lower portion 151p-2 of the protrusion 151p of the first barrier layer and the upper portion 151p-1 of the protrusion 151p of the first barrier layer.

In the semiconductor device 3 according to example embodiments of the present inventive concepts, the thickness of the upper portion 151p-1 of the protrusion 151p of the first barrier layer may be thinner than the thickness of lower portion 151p-2 of the protrusion 151p of the first barrier layer.

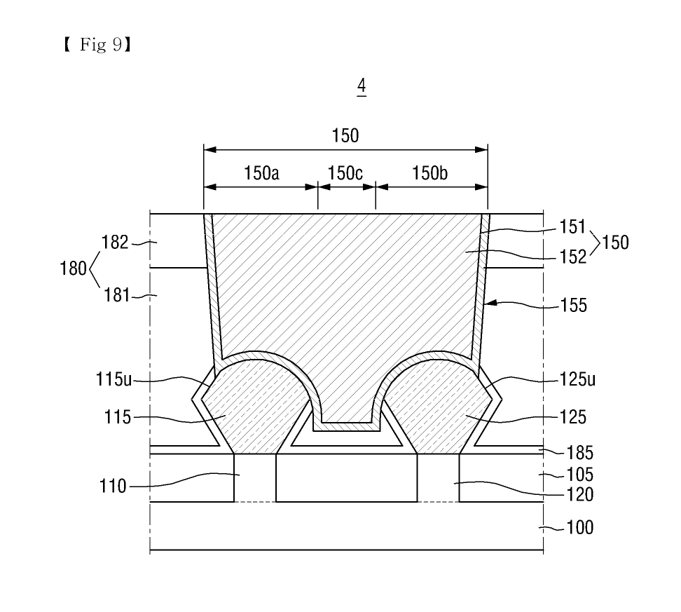

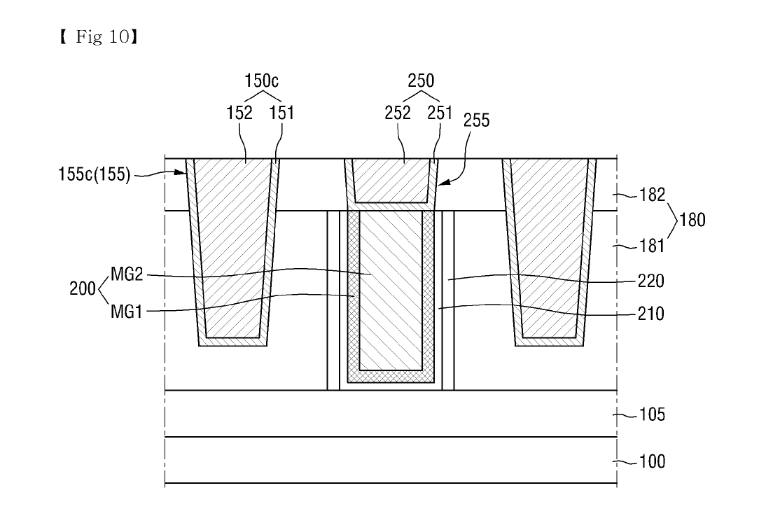

FIG. 9 and FIG. 10 are diagrams illustrating a semiconductor device according to example embodiments of the present inventive concepts. For convenience of description, differences from the example embodiment described with reference to FIG. 1 to FIG. 6 will be mainly explained. For reference, FIG. 9 may be a cross-sectional view taken along the line C-C of FIG. 1, and FIG. 10 may be a cross-sectional view taken along the line D-D of FIG. 1.

Referring to FIG. 9 and FIG. 10, in a semiconductor device 4 according to example embodiments of the present inventive concepts, the height of the connection portion 150c of the first contact may be higher than the height of the first portion 150a of the first contact and the height of the second portion 150b of the first contact.

Since the height of the connection portion 150c of the first contact may be higher than the height of the first portion 150a of the first contact overlapping the first source/drain 115 and higher than the height of the second portion 150b of the first contact overlapping the second source/drain 125, a part of the connection portion 150c of the first contact may pass through a gap between the first source/drain 115 and the second source/drain 125.

However, since the first contact 150 may not be in contact with the field insulating layer 105, the interlayer insulating layer 180 may be interposed between the connection portion 150c of the first contact and the field insulating layer 105. When measured from the substrate 100, the bottom surface of the connection portion 150c of the first contact may be higher than the upper surface of the field insulating layer 105.

When measured from the upper surface of the interlayer insulating layer 180, the bottom surface of the first portion 150a of the first contact and the bottom surface of the second portion 150b of the first contact may be shallower than the bottom surface of the connection portion 150c of the first contact.

On the other hand, when measured from the upper surface of the field insulating layer 105, the bottom surface of the first portion 150a of the first contact and the bottom surface of the second portion 150b of the first contact may be higher than the bottom surface of the connection portion 150c of the first contact. In other words, when measured from the upper surface of the field insulating layer 105, the upper surface 115u of the first source/drain and the upper surface 125u of the second source/drain may be higher than the bottom surface of the connection portion 150c of the first contact.

In addition, the height of the connection portion 150c of the first contact may be higher than the height of the second contact 250. Accordingly, a part of the connection portion 150c of the first contact may overlap the gate electrode 200 in the thickness direction of the substrate 100.

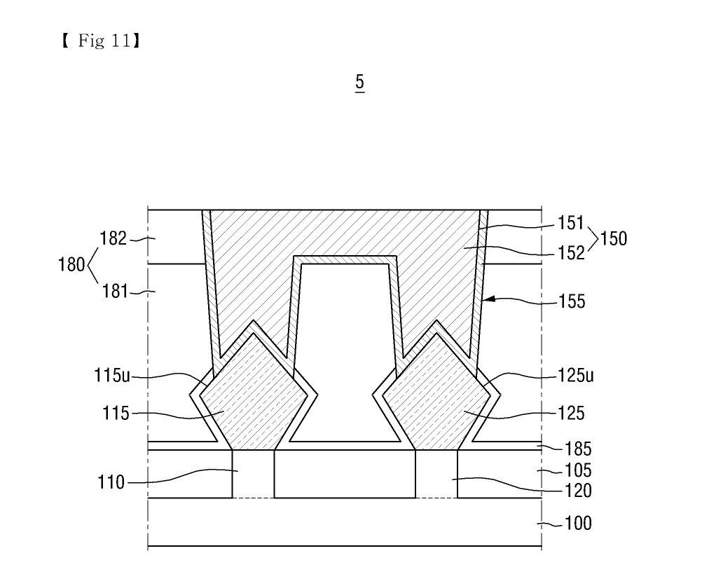

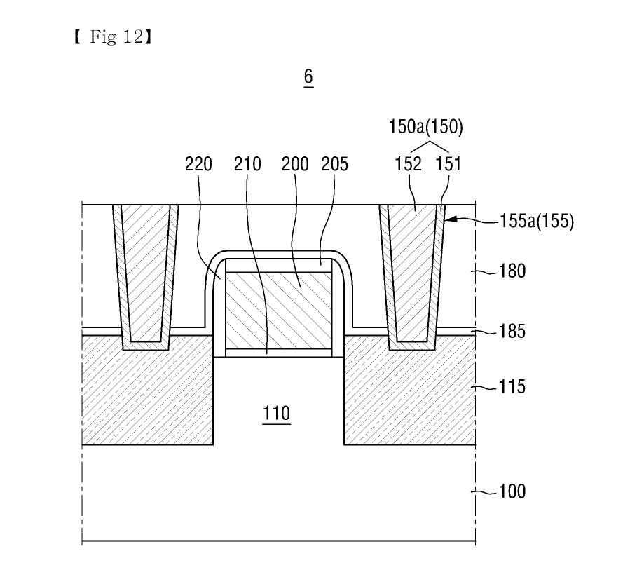

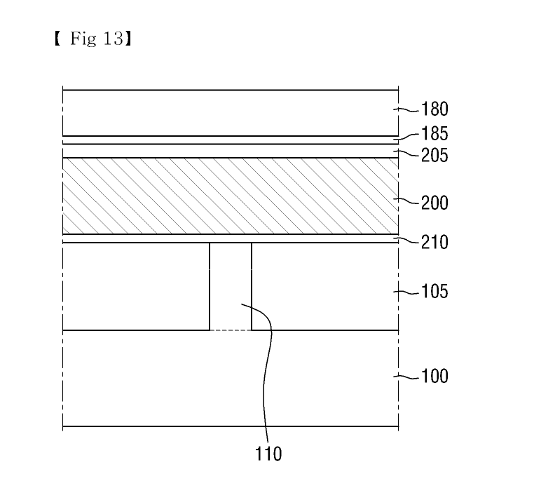

FIG. 11 is a diagram illustrating a semiconductor device according to example embodiments of the present inventive concepts. FIG. 12 and FIG. 13 are diagrams illustrating a semiconductor device according to example embodiments of the present inventive concepts. For convenience of description, differences from the example embodiment described with reference to FIG. 1 to FIG. 6 will be mainly explained.

For reference, FIG. 11 may be a cross-sectional view taken along the line C-C of FIG. 1. FIG. 12 may be a cross-sectional view taken along the line A-A of FIG. 1, and FIG. 13 may be a cross-sectional view taken along the line B-B of FIG. 1.

Referring to FIG. 11, in a semiconductor device 5 according to example embodiments of the present inventive concepts, the upper surface 115u of the first source/drain and the upper surface 125u of the second source/drain may not be etched, and thus, the upper surface 115u of the first source/drain and the upper surface 125u of the second source/drain may have a facet overall which might be formed during a formation of the first source/drain 115 and the second source/drain 125.

That is, a part of the bottom surface of the first contact 150 may be formed along the facet which is formed during the formation of the first source/drain 115 and the second source/drain 125.

Referring to FIG. 12 and FIG. 13, in a semiconductor device 6 according to example embodiments of the present inventive concepts, the upper surface of the first active region 110 and the upper surface of the second active region 120 may not protrude further than the upper surface of the field insulating layer 105.

The gate insulating layer 210 formed between the gate electrode 200 and the first active region 110 may not protrude further upward than the upper surface of the field insulating layer 105.

Furthermore, the gate insulating layer 210 may be formed between the gate electrode 200 and the first active region 110 and between the gate electrode 200 and the second active region 120, and may not be formed between the side walls of the gate electrode 200 and the gate spacer 220.

In the semiconductor 6 according to example embodiments of the present inventive concepts, the gate electrode 200 may include TiN, TaN, W, Al, Si, SiGe, or metal silicide.

The gate hard mask 205 may be formed on the gate electrode 200. The gate hard mask 205 may include, for example, a silicon nitride layer, a silicon oxide layer, a silicon oxynitride layer, and a combination thereof.

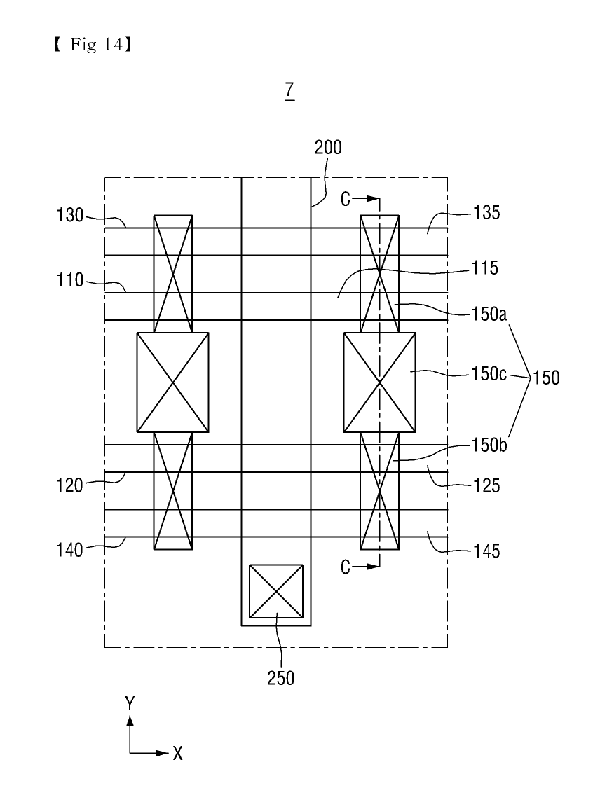

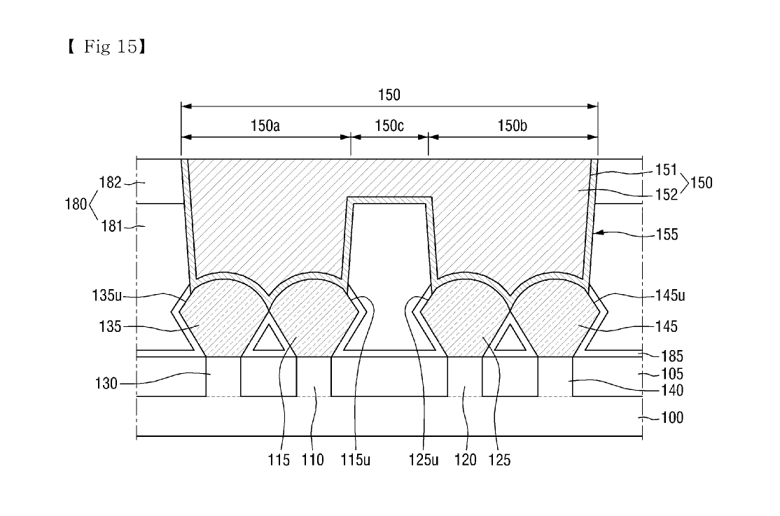

FIG. 14 is a layout diagram illustrating a semiconductor device according to example embodiments of the present inventive concepts. FIG. 15 is a cross-sectional view taken along the line C-C of FIG. 14. For convenience of description, differences from the example embodiment described with reference to FIG. 1 to FIG. 6 will be mainly explained.

Referring to FIG. 14 and FIG. 15, a semiconductor device 7 according to example embodiments of the present inventive concepts may further include a third active region 130 and a third source/drain 135.

Furthermore, the semiconductor device 7 according to example embodiments of the present inventive concepts may further include a fourth active region 140 and a fourth source/drain 145, however, it is merely for convenience of description, but not limited thereto.

That is, either the first portion 150a of the first contact or the second portion 150b of the first contact may be connected to one elevated source/drain.

The first to fourth active regions 110, 120, 130 and 140 may extend in the first direction X. The first to fourth active regions 110, 120, 130 and 140 may be spaced apart from each other.

Furthermore, the first to fourth active regions 110, 120, 130 and 140 may be arranged in the second direction Y. The third active region 130, the first active region 110, the second active region 120 and the fourth active region 140 may be sequentially arranged in the second direction Y.

Similarly to the case of the first active region 110 and the second active region 120, the field insulating layer 105 may cover a part of side walls of the third active region 130 and a part of side walls of the fourth active region 140.

The gate electrode 200 may extend in the second direction Y so as to intersect the first to fourth active regions 110, 120, 130 and 140. The gate electrode 200 may be formed on the first to fourth active regions 110, 120, 130 and 140 and the field insulating layer 105.

The third source/drain 135 may be formed at both sides of the gate electrode 200. The third source/drain 135 may be formed to overlap the first active region 110. The third source/drain 135 may be an elevated source/drain.

The third source/drain 135 may be in contact with the first source/drain 115, but may not be in contact with the second source/drain 125. More specifically, the first source/drain 115 and the third source/drain 135 which are on one side of the gate electrode 200 may be in contact with each other.

The fourth source/drain 145 may be formed at both sides of the gate electrode 200. The fourth source/drain 145 may be formed to overlap the fourth active region 140. The fourth source/drain 145 may be a raised source/drain.

The fourth source/drain 145 may be in contact with the second source/drain 125, but may not be in contact with the first source/drain 115. More specifically, the second source/drain 125 and the fourth source/drain 145 which are on one side of the gate electrode 200 may be in contact with each other.

As shown in FIG. 15, the third source/drain 135 may be formed on the third active region 130, and the fourth source/drain 145 may be formed on the fourth active region 140.

The first contact 150 may be connected to the first to fourth source drains 115, 125, 135 and 145. In other words, the first contact 150 may be a common contact to the first to fourth source drains 115, 125, 135 and 145.

The first portion 150a of the first contact may be disposed on the first source/drain 115 and the third source/drain 135 which are in contact with each other. The first portion 150a of the first contact may extend onto the third source/drain 135.

The first portion 150a of the first contact may overlap the first source/drain 115 and the third source/drain 135, but may not overlap the fourth source/drain 145.

The second portion 150b of the first contact may be disposed on the second source/drain 125 and the fourth source/drain 145 which are in contact with each other. The second portion 150b of the first contact may extend onto the fourth source/drain 145.

The second portion 150b of the first contact may overlap the second source/drain 125 and the fourth source/drain 145, but may not overlap the third source/drain 135.

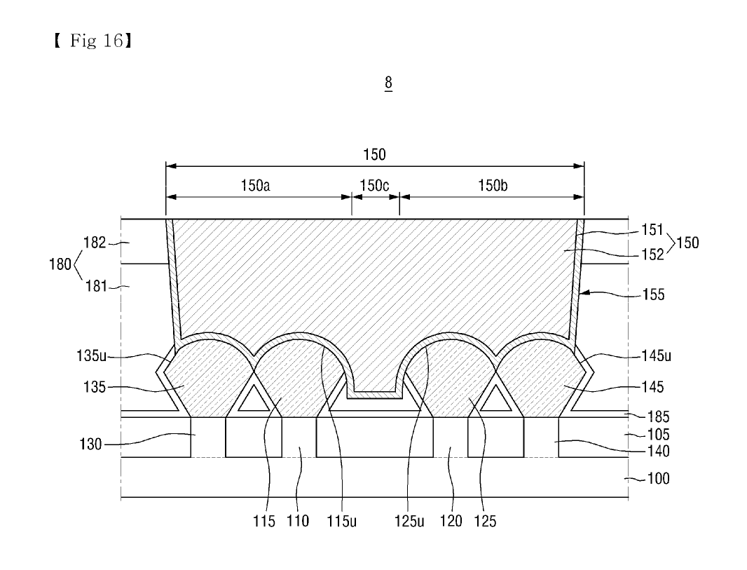

FIG. 16 is a diagram illustrating a semiconductor device according to example embodiments of the present inventive concepts. For convenience of description, differences from the example embodiment described with reference to FIG. 14 and FIG. 15 will be mainly explained.

Referring to FIG. 16, in the semiconductor device 8 according to example embodiments of the present inventive concepts, the height of the connection portion 150c of the first contact may be higher than the height of the first portion 150a of the first contact and higher than the height of the second portion 150b of the first contact.

When measured from the upper surface of the field insulating layer 105, the bottom surface of the first portion 150a of the first contact and the bottom surface of the second portion 150b of the first contact may be higher than the bottom surface of the connection portion 150c of the first contact.

In other words, when measured from the upper surface of the field insulating layer 105, the upper surface of the first source/drain, the upper surface of the second source/drain, an upper surface 135u of the third source/drain, and an upper surface 145u of the fourth source/drain may be higher than the bottom surface of the connection portion 150c of the first contact.

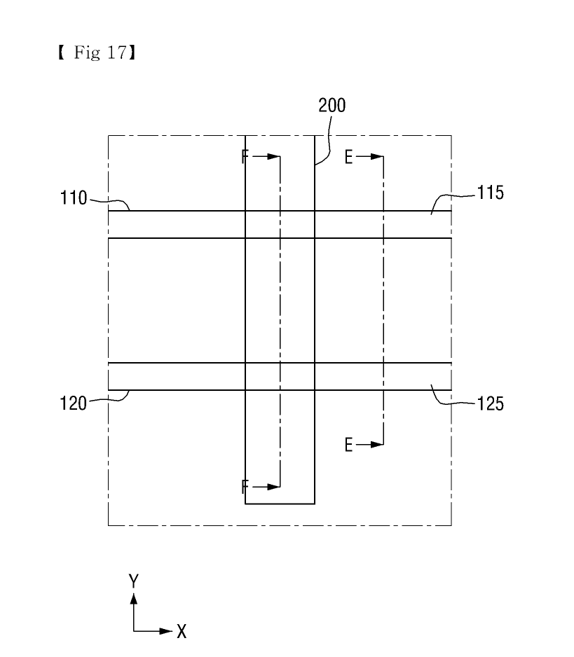

A method of fabricating a semiconductor device according to example embodiments of the present inventive concepts will be explained with reference to FIG. 17 to FIG. 24. The semiconductor device according to example embodiments of the present inventive concepts can be fabricated by the method of fabricating a semiconductor device according to example embodiments of the present inventive concepts.

FIG. 17 to FIG. 24 are diagrams illustrating intermediate process steps of a method of fabricating a semiconductor device according to example embodiments of the present inventive concepts.

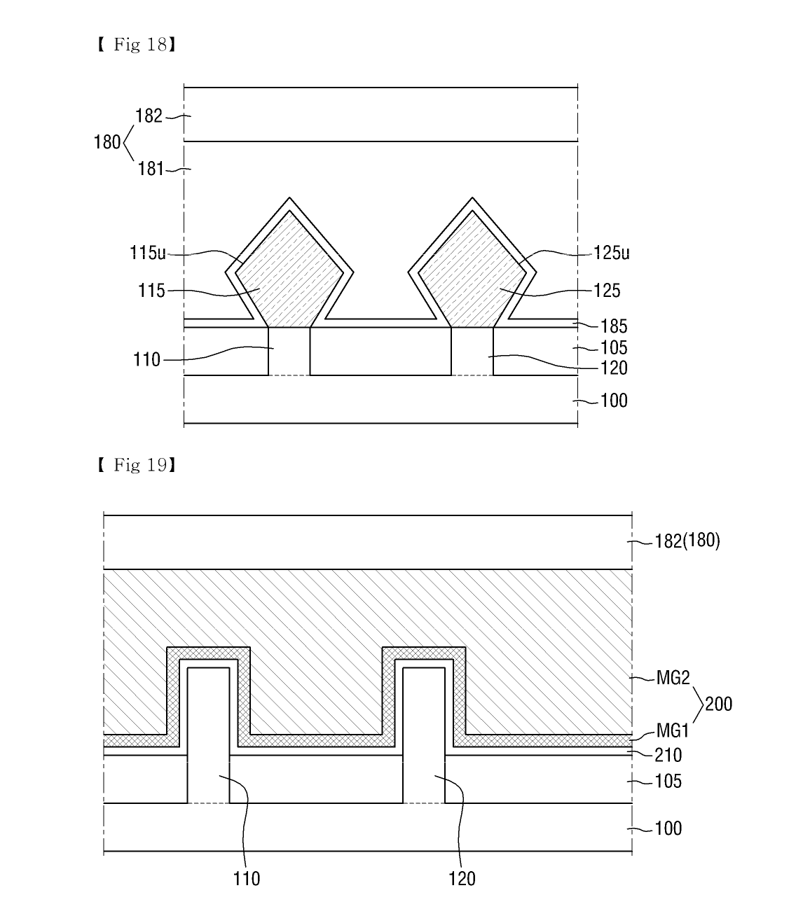

For reference, FIG. 18 is a cross-sectional view taken along the line E-E of FIG. 17, and FIG. 19 is a cross-sectional view taken along the line F-F of FIG. 17.

Referring to FIG. 17 to FIG. 19, the gate electrode 200 intersecting the first active region 110 and the second active region 120 may be formed on the first active region 110 and the second active region 120 spaced apart from each other.

Furthermore, the first source/drain 115 overlap the first active region 110 may be formed at both sides of the gate electrode 200. The second source/drain 125 overlap the second active region 120 may be formed at both sides of the gate electrode 200.

In example embodiments, the first source/drain 115 and the second source/drain 125 which are formed at one side of the gate electrode 200 may be spaced apart from each other and may not be in contact with each other.

As shown in FIG. 17 to FIG. 19, the first source/drain 115 and the second source/drain 125 may be formed, and then the gate electrode 200 may be formed through a replacement process, but the present disclosure is not limited thereto.

Subsequently, the interlayer insulating layer 180 may be formed on the field insulating layer 105 so as to cover the gate electrode 200, the first source/drain 115 and the second source/drain 125.

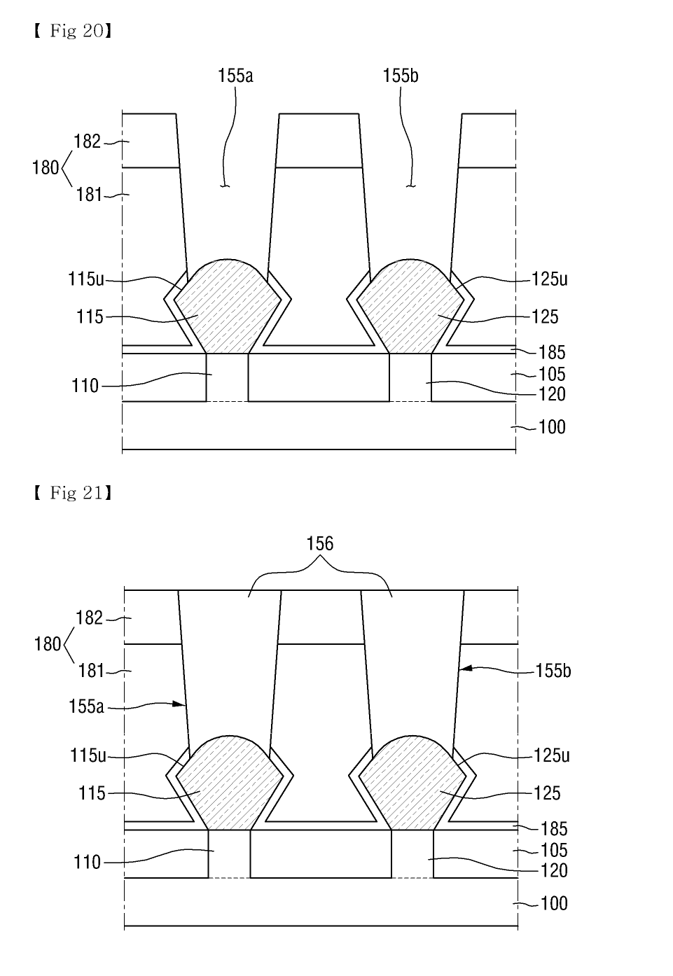

Referring to FIG. 20, the first trench 155a overlap the first source/drain 115 and the second trench 155b overlap the second source/drain 125 may be formed within the interlayer insulating layer 180.

The first trench 155a may expose the upper surface of the first source/drain 115 and the second trench 155b may expose the upper surface of the second source/drain 125.

The first trench 155a and the second trench 155b may be spaced apart from each other by the interlayer insulating layer 180 and thus may not be connected with each other.

The first trench 155a and the second trench 155b may be formed through an etching process. A part of the upper surface of the first source/drain 115 and a part of the upper surface of the second source/drain 125 may be etched during an etching process for forming the first trench 155a and the second trench 155b.

Referring to FIG. 21, sacrificial patterns 156 may be formed within the interlayer insulating layer 180 so as to fill the first trench 155a and the second trench 155b.

The sacrificial patterns 156 may include, for example, a material having good gap-fill ability. Furthermore, the sacrificial patterns 156 may include a material that can be more easily removed through an ashing process.

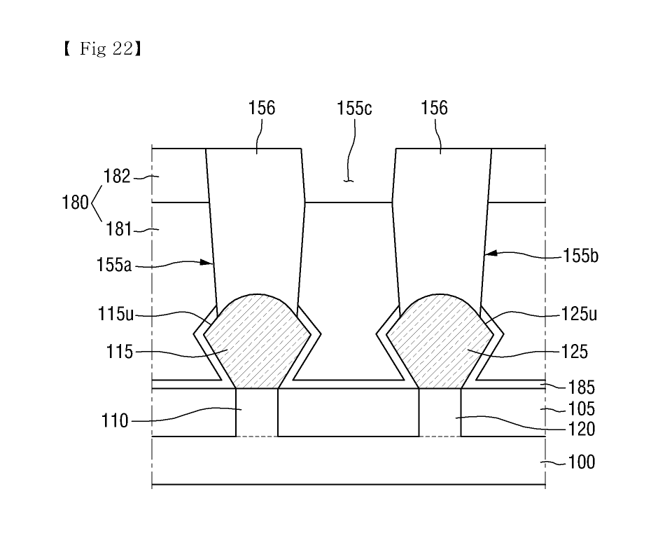

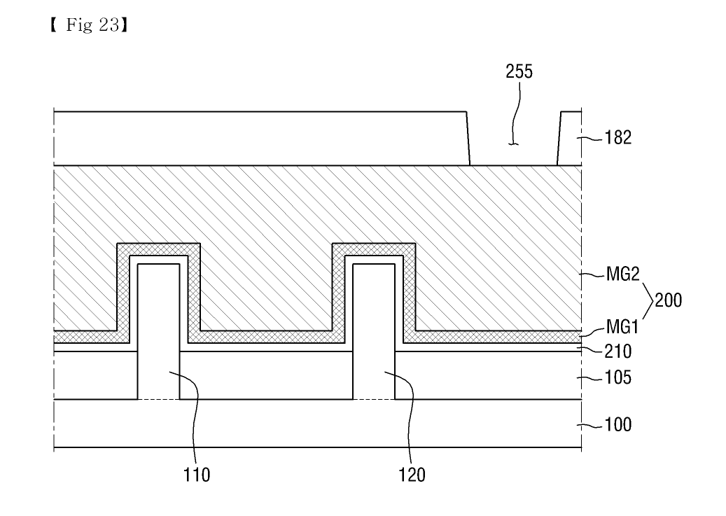

Referring to FIG. 22 and FIG. 23, the connection trench 155c may be formed within the interlayer insulating layer 180 so as to interconnect the first trench 155a and the second trench 155b. Furthermore, the second contact hole 255 may be formed in the interlayer insulating layer 180 so as to expose the upper surface of the gate electrode 200.

The connection trench 155c may be formed between first trench 155a and the second trench 155b.

The connection trench 155c and the second contact hole 255 may be formed through an etching process. The connection trench 155c and the second contact hole 255 may be formed simultaneously in the interlayer insulating layer 180.

Sidewall of the connection trench 155c may be sacrificial patterns 156 which fill the first trench 155a and second trench 155b, respectively.

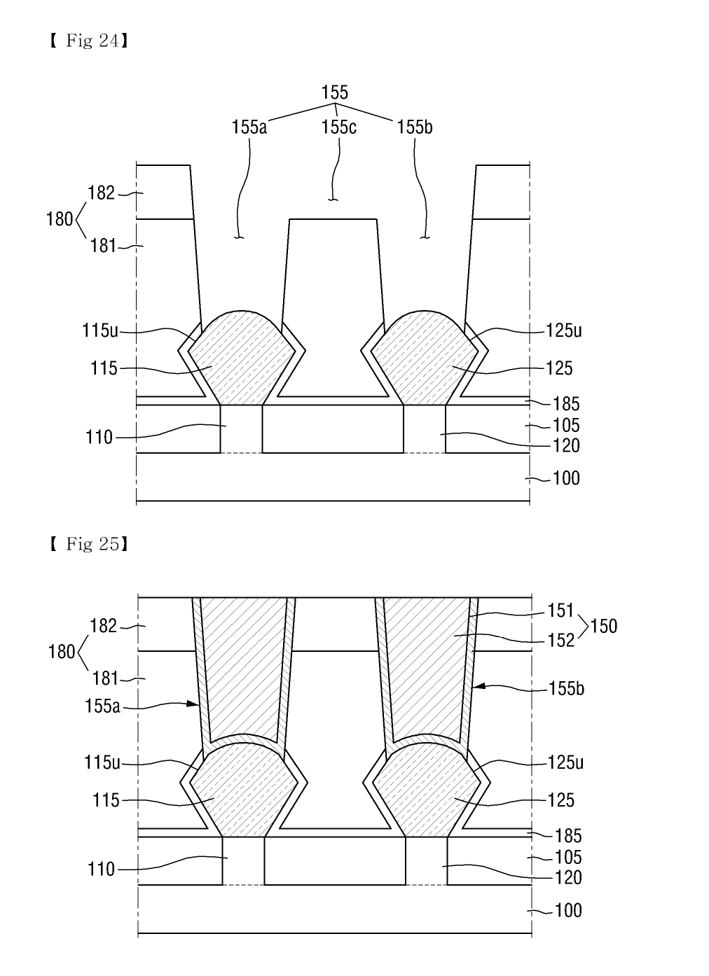

Referring to FIG. 24, the sacrificial patterns 156 which fill the first trench 155a and second trench 155b may be removed.

Thus, the first contact hole 155 including the first trench 155a, the second trench 155b and the connection trench 155c may be formed. The upper surface 115u of the first source/drain and the upper surface 125u of the second source/drain may be exposed by the first contact hole 155.

Referring back to FIG. 4, the first barrier layer 151 may be formed along the sidewall and bottom surface of the first contact hole 155, and the first filling layer 152 may be formed to fill the first contact hole 155, thereby forming the first contact 150 within the interlayer insulating layer 180.

Furthermore, the second barrier layer 251 may be formed along the sidewall and bottom surface of the second contact hole 255, and the second filling layer 252 may be formed to fill the second contact hole 255, thereby forming the second contact 250 within the interlayer insulating layer 180.

The first contact 150 and the second contact 250 may be formed simultaneously, but are not limited thereto.

A method of fabricating a semiconductor device according to example embodiments of the present inventive concepts will be explained with reference to FIG. 17 to FIG. 20, and FIG. 25 to FIG. 27. The semiconductor device according to example embodiments of the present inventive concepts can be fabricated by the method of fabricating a semiconductor device according to example embodiments of the present inventive concepts.

FIG. 25 to FIG. 27 are diagrams illustrating intermediate steps of a method of fabricating a semiconductor device according to example embodiments of the present inventive concepts.

Referring to FIG. 25, the first portion 150a of the first contact connected to the first source/drain 115 and the second portion 150b of the first contact connected to the second source/drain 125 may be formed in the interlayer insulating layer 180.

The first portion 150a of the first contact may be formed by filling the first trench 155a, and the second portion 150b of the first contact may be formed by filling the second trench 155b.

The first portion 150a of the first contact and the second portion 150b of the first contact may be formed simultaneously.

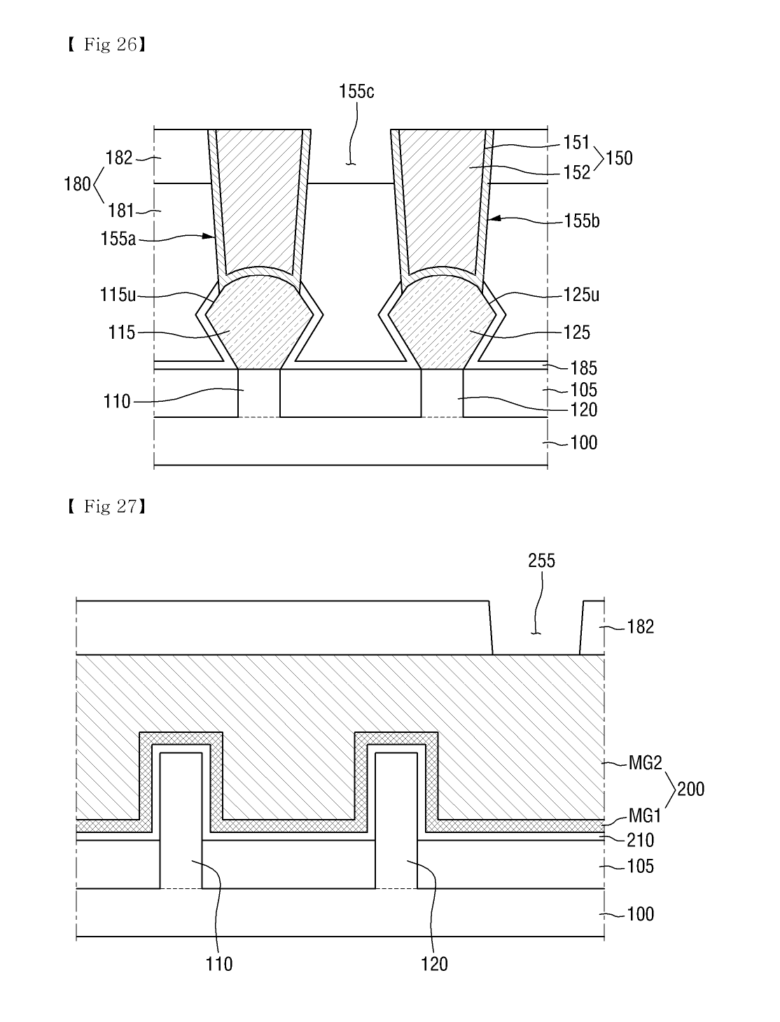

Referring to FIG. 26 and FIG. 27, the connection trench 155c may be formed in the interlayer insulating layer 180 so as to interconnect the first trench 155a and the second trench 155b. The connection trench 155c may have, as sidewall thereof, the first portion 150a of the first contact and the second portion 150b of the first contact.

That is, the connection trench 155c may be defined by the interlayer insulating layer 180, the first portion 150a of the first contact and the second portion 150b of the first contact.

Furthermore, the second contact hole 255 is formed in the interlayer insulating layer 180 so as to expose the upper surface of the gate electrode 200.

Referring back to FIG. 7 or FIG. 8, the connection portion 150c of the first contact may be formed in the interlayer insulating layer 180 such that the connection portion 150c may contact the first portion 150a of the first contact and the second portion 150b of the first contact and fill the connection trench 155c.

Thus, the first contact 150 including the first portion 150a, the second portion 150b and the connection portion 150c may be formed within the interlayer insulating layer 180.

Furthermore, the second contact 250 may be formed within the interlayer insulating layer 180 so as to fill the second contact hole 255.

The connection portion 150c of the first contact and the second contact 250 may be formed simultaneously, but are not limited thereto.

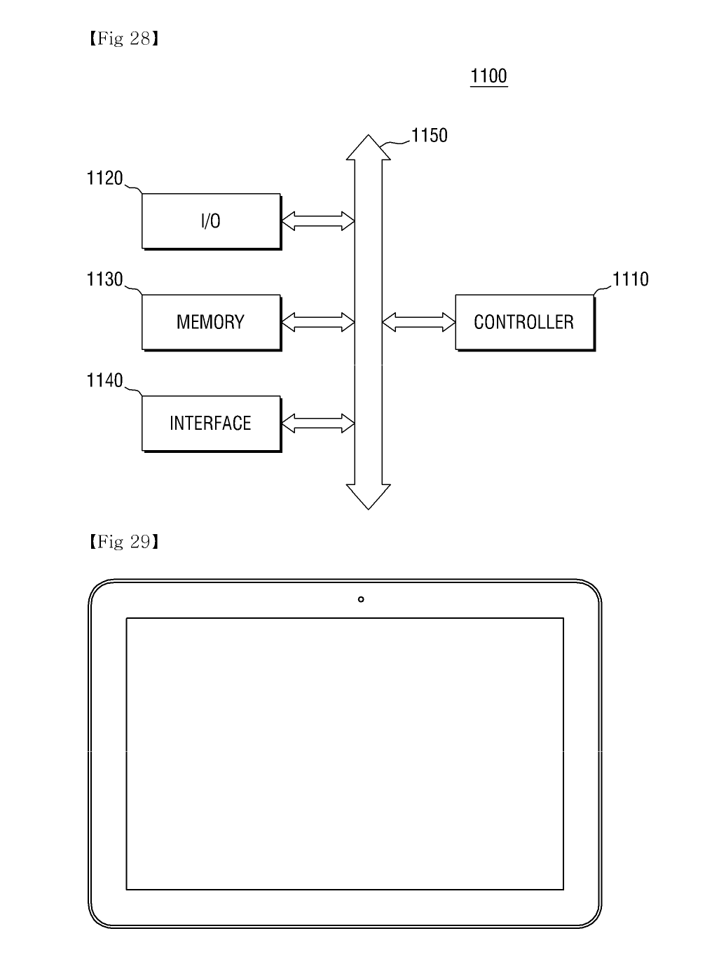

FIG. 28 is a block diagram of an electronic system including semiconductor devices according to example embodiments of the present inventive concepts.

Referring to FIG. 28, an electronic system 1100 according to example embodiments of the present inventive concepts may include a controller 1110, an input/output (I/O) device 1120, a memory device 1130, an interface 1140 and a bus 1150. The controller 1110, the input/output device 1120, the memory device 1130 and/or the interface 1140 may be coupled with each other through the bus 1150. The bus 1150 may serve as a path for data movement.

The controller 1110 may include at least one of a microprocessor, a digital signal processor, a microcontroller, and logic elements capable of performing functions similar to those of the microprocessor, the digital signal processor, and the microcontroller. The input/output device 1120 may include a keypad, a keyboard, and/or a display device. The memory device 1130 may store therein data and/or instructions. The interface 1140 may perform the function of transmitting data to a communication network or receiving data from the communication network. The interface 1140 may be of a wired or wireless type. For example, the interface 1140 may include an antenna or a wired/wireless transceiver. Although not shown, the electronic system 1100 may further include high speed DRAM and/or SRAM as an operation memory for improving an operation of the controller 1110. The semiconductor devices according to example embodiments of the present inventive concepts may be provided within the memory device 1130, or provided as a part of the controller 1110 and/or the input/output device 1120.

The electronic system 1100 may be applicable to a personal digital assistant (PDA), a portable computer, a web tablet, a wireless phone, a mobile phone, a digital music player, a memory card, or all electronic products that can transmit and/or receive information in a wireless environment.

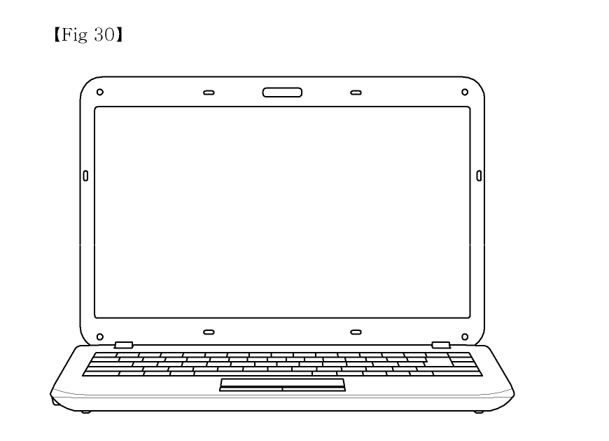

FIG. 29 and FIG. 30 are diagrams illustrating examples of a semiconductor system to which semiconductor devices according to example embodiments of the present inventive concepts can be applied. FIG. 29 illustrates a tablet PC, and FIG. 30 illustrates a notebook computer. At least one of the semiconductor devices according to example embodiments of the present inventive concepts can be employed in a tablet PC and/or a notebook computer. It may be readily apparent to those skilled in the art that the semiconductor devices according to example embodiments of the present inventive concepts can be also applied to other integrated circuit devices which are not illustrated herein.

While the present inventive concepts have been particularly shown and described with reference to example embodiments thereof, it will be understood by those of ordinary skill in the art that various changes in form and details may be made therein without departing from the spirit and scope of the present inventive concepts as defined by the following claims. Example embodiments should be considered in all respects as illustrative and not restrictive, reference being made to the appended claims rather than the foregoing description to indicate the scope of example embodiments.

1. A semiconductor device comprising:
a first active region and a second active region spaced apart from each other;
a gate electrode on the first active region and the second active region, the gate electrode intersecting the first active region and the second active region;
a first source/drain and a second source/drain on sides of the gate electrode, the first source/drain and the second source/drain spaced apart from each other; and
a contact including a first portion on the first source/drain, a second portion on the second source drain and a connection portion interconnecting the first portion and the second portion, the first portion and the second portion having an upper surface arranged to be coplanar with an upper surface of the connection portion, and the first portion and the second portion having a height in a vertical direction different from a height of the connection portion.

2. The semiconductor device of claim 1, wherein the height of the first portion and the height of the second portion is greater than the height of the connection portion.

3. (canceled)

4. The semiconductor device of claim 1, wherein the connection portion is between the first source/drain and the second source/drain.

5. The semiconductor device of claim 1, further comprising:
an interlayer insulating layer covering the gate electrode, the first source/drain and the second source/drain, the interlayer insulating layer including a contact hole having a first trench portion, a second trench portion and a connection trench portion,
wherein the first trench corresponds to the first portion of the contact, the second trench corresponds to the second portion of the contact, and the connection trench corresponds to the connection portion of the contact.

6. The semiconductor device of claim 5, wherein a height from an upper surface of the gate electrode to an upper surface of the interlayer insulating layer is the same as the height of the connection portion.

7. The semiconductor device of claim 5, wherein
the contact includes a barrier layer along a side wall and a bottom surface of the contact hole, and a filling layer on the barrier layer to fill the contact hole, and
the filling layer is not divided by the barrier layer.

8. The semiconductor device of claim 5, wherein
the contact includes a barrier layer along a side wall and a bottom surface of the contact hole and a filling layer on the barrier layer to fill the contact hole, and
the barrier layer includes a protrusion protruding from the bottom surface of the contact hole.

9. The semiconductor device of claim 8, wherein the filling layer is divided into at least two sections by the protrusion of the barrier layer.

10-11. (canceled)

12. The semiconductor device of claim 1, further comprising:
a third active region adjacent to and spaced apart from the first active region, the third active region intersecting the gate electrode; and
a third source/drain on sides of the gate electrode, the third source/drain in contact with the first source/drain and not in contact with the second source/drain.

13. The semiconductor device of claim 12, wherein the first portion extends onto the third source/drain.

14. The semiconductor device of claim 1, wherein the first source/drain and the second source/drain are elevated source/drains.

15. The semiconductor device of claim 1, wherein each of the first active region and the second active region is a fin-type active pattern.

16-17. (canceled)

18. A semiconductor device comprising:
a first active region and a second active region spaced apart from each other;
a gate electrode on the first active region and the second active region, the gate electrode intersecting the first active region and the second active region;
a first source/drain and a second source/drain on sides of the gate electrode and spaced apart from each other, the first source/drain overlapping the first active region and the second source/drain overlapping the second active region;
an interlayer insulating layer covering the gate electrode, the first source/drain and the second source/drain; and
a contact in the interlayer insulating layer, the contact including a first portion on the first source/drain, a second portion on the second source/drain and a connection portion interconnecting the first portion and the second portion, the first portion having a bottom surface and the second portion having a bottom surface lower than a bottom surface of the connection portion based on an upper surface of the interlayer insulating layer.

19. The semiconductor device of claim 18, wherein the bottom surface of the connection portion is higher than an upper surface of the first source/drain and an upper surface of the second source/drain based on the upper surface of the interlayer insulating layer.

20. The semiconductor device of claim 18, wherein an upper surface of the first portion, an upper surface of the second portion, and an upper surface of the connection portion are arranged to be coplanar with each other.

21. The semiconductor device of claim 18, wherein
the interlayer insulating layer includes a contact hole corresponding with the contact,
the contact hole has an uneven bottom surface corresponding to the bottom surface of the first portion, the bottom surface of the second portion and the bottom surface of the connection portion, and
the contact includes a barrier layer along a side wall and a bottom surface of the contact hole and a filling layer on the barrier layer to fill the contact hole.

22-24. (canceled)

25. A semiconductor device comprising:
first, second, third and fourth fin-type active patterns spaced apart from each other and sequentially arranged in one direction;
a field insulating layer covering a portion of each side wall of the first, second, third and fourth fin-type active patterns;
a gate electrode on the field insulating layer, the gate electrode intersecting the first, second, third and fourth fin-type active patterns and extending in the one direction;
a first source/drain on the first fin-type active pattern and a second source/drain on the second fin-type active pattern, the first and second source/drains on sides of the gate electrode and contacting each other;
a third source/drain on the third fin-type active pattern and a fourth source/drain on the fourth fin-type active pattern, the third and fourth source/drains on sides of the gate electrode and contacting each other, the third source/drain not contacting the second source/drain; and
a contact including a first portion connected to the first source/drain and the second source/drain, a second portion connected to the third source/drain and the fourth source/drain and a connection portion interconnecting the first portion and the second portion, the first portion and the second portion having an upper surface arranged to be coplanar with an upper surface of the connection portion, and the first portion and the second portion having a height different from a height of the connection portion.

26. The semiconductor device of claim 25, wherein a bottom surface of the first portion and a bottom surface of the second portion are lower than a bottom surface of the connection portion based on an upper surface of the field insulating layer.

27. The semiconductor device of claim 25, wherein a part of the connection portion passes through a gap between the second source/drain and the third source/drain.

28. The semiconductor device of claim 27, wherein a bottom surface of the connection portion is higher than an upper surface of the field insulating layer.

29-31. (canceled)
